(19) United States
(12) Patent Application Publication
(10) Pub. No.: US 2009/0098468 A1
(43) Pub. Date: Apr. 16, 2009

(54) PHOTO-MASKS AND METHODS OF FABRICATING PHOTONIC CRYSTAL DEVICES

(75) Inventors: THOMAS K. GAYLORD, Atlanta, GA (US); Justin L. Stay, Suwanee, GA (US); James D. Meindl, Marietta, GA (US)

Correspondence Address: Troutman Sanders LLP/Marco/GA Tech;RYAN A. SCHNEIDER, ESQ., 600 Peachtree Street, 5200 Bank of America Plaza, Atlanta, GA, 30308, US

(73) Assignee: Georgia Tech Research Corporation, Atlanta, GA (US)

(21) Appl. No.: 11/871,834

(22) Filed: Oct. 12, 2007

(51) Int. Cl. G02B 27/44; G03F 1/00

(52) U.S. Cl. 430/5; 359/566; 430/290

(57) ABSTRACT

Improved photo-masks for use in fabricating photonic crystal devices are disclosed herein. Methods of making photonic crystal devices, as well as the photonic crystal devices fabricated therefrom, are also disclosed. The photo-mask can include a body element and one or more sets of diffractive elements and/or refractive elements disposed on the body element or within the body element. Each set of diffractive elements and/or refractive elements can be configured to produce four non-coplanar beams of light when a beam of light is passed through it. Each set of four non-coplanar beams of light can be used to interferometrically produce a specific photonic crystal structure at a specific location within a photosensitive recording material.

### TECHNICAL FIELD

The various embodiments of the present invention relate generally to photonic crystals, and more particularly, to photo-masks for use in fabricating photonic crystal devices, and to methods of making the photo-masks and photonic crystal devices.

### BACKGROUND

Photonic crystals are periodic optical structures that are designed to affect the motion of photons using the physical phenomenon of diffraction. This is similar to the way that periodicity in a semiconductor crystal affects the motion of electrons. Specifically, photonic crystals are made from periodic dielectric or metallo-dielectric structures that are designed to affect the propagation of electromagnetic waves in the same way as the periodic potential in a semiconductor crystal affects the electron motion by defining allowed and forbidden electronic energy bands. The absence of allowed propagating electromagnetic modes inside the photonic crystal structures, in a range of wavelengths called a photonic band gap, gives rise to distinct optical phenomena such as inhibition of spontaneous emission, high-reflecting omni-directional mirrors, and low-loss or lossless waveguiding, among others.

Owing to this ability to control and manipulate the flow of light, photonic crystals find use in many applications. For example, one-dimensional photonic crystals, in the form of thin-films, are found in low- and high-reflection coatings on lenses and mirrors as well as in color-changing paints and inks. In addition, based on its potential to offer lossless control of light propagation at a size scale near the order of the wavelength of light, photonic crystal-based technology has the potential to produce the first truly dense integrated photonic circuits and systems (DIPCS). Individual components that are actively being developed include resonators, antennas, sensors, multiplexers, filters, couplers, switches, and the like. The integration of these components would produce DIPCS that would perform functions such as image acquisition, target recognition, image processing, optical interconnections, Analog-to-Digital conversion, sensing, and the like. Further, the resulting DIPCS would be very compact in size and highly field-portable.

Since the basic physical phenomenon is based on diffraction, the periodicity of the photonic crystal structure has to be in the same length-scale as approximately half the wavelength of the electromagnetic waves. For example, applications using light at telecommunications wavelengths require structures to be fabricated at microscale and nanoscale dimensions. This, however, is the major challenge to commercial implementation of photonic crystal-based structures. More specifically, there is currently a lack of systematic fabrication procedures for reliable and reproducible production of microscale and nanoscale photonic crystal structures with sufficient precision to prevent scattering losses blurring the photonic crystal properties.

Most techniques for fabricating 2- and 3-dimensional photonic crystals are based on those used for integrated circuits, such as photolithography and etching techniques. However, these methods are not optimal. To circumvent these methods, which require complex machinery, alternative approaches have been proposed. These include self-assembling photonic crystal structures from colloids or using fiber drawing techniques developed for communications fiber to grow photonic crystal-fibers. However, these methods do not lend themselves well to reliable and reproducible commercial scale production.

Accordingly, there remains a need for improved methods of producing nanoscale photonic crystal structures or devices. It is to the provision of such methods that the various embodiments of the present invention are directed. More specifically, it is to the provision of improved photo-masks for use in fabricating photonic crystal devices, as well as the associated photonic crystal device fabricated therefrom, that the various embodiments of the present invention are directed.

### BRIEF SUMMARY

Various embodiments of the present invention are directed to photo-masks for use in fabricating 1-, 2-, or 3-dimensional photonic crystal devices. Some embodiments are also directed to methods of fabricating such devices. Still some other embodiments are directed to the fabricated photonic crystal devices.

Broadly described, a photo-mask according to an embodiment of the present invention can include a body element and a set of diffractive elements and/or refractive elements disposed on the body element or within the body element. The set of diffractive elements and/or refractive elements can be configured to produce four non-coplanar beams of light when a beam of light is passed through it. The photo-mask can include additional sets of diffractive elements and/or refractive elements disposed on the body element or within the body element. Each additional set of diffractive elements and/or refractive elements is also configured to produce four non-coplanar beams of light when a beam of light is passed through it.

Each set of diffractive elements and/or refractive elements generally includes two or more diffractive elements and/or refractive elements. According to one embodiment, each set of diffractive elements and/or refractive elements comprises four diffractive elements and/or refractive elements. The diffractive elements can include volume gratings or surface-relief gratings; and the refractive elements can include materials having a different index of refraction than the body element.

In addition, the photo-mask can further include a chrome layer, an absorption layer, a retarder layer, or more than one of the foregoing layers.

An apparatus for producing a photonic crystal device according to an embodiment of the present invention can include a photo-mask and a recording material, which can be a photosensitive recording material. Each set of diffractive elements and/or refractive elements of the photo-mask is configured to individually produce four non-coplanar beams of light when a beam of light is passed therethrough such that each set of four non-coplanar beams of light interferometrically produce a separate photonic crystal structure at a specific location in the recording material.

A method of fabricating a photonic crystal device according to an embodiment of the present invention can include generating a light beam that can be directed into a photo-mask. Each set of diffractive elements and/or refractive elements in the photo-mask produces four non-coplanar beams of light. Each set of four non-coplanar beams of light can be focused in a recording material to interferometrically produce a separate photonic crystal structure in the recording material.

If simultaneous production of multiple photonic crystal structures in the recording material is not desired, the methods can be repeated to produce multiple photonic crystal structures in the recording material by aligning the photo-mask over a second portion of the recording material and repeating the methods on the second portion of the recording material.

Other aspects and features of embodiments of the present invention will become apparent to those of ordinary skill in the art, upon reviewing the following detailed description in conjunction with the accompanying figures.

### BRIEF DESCRIPTION OF THE DRAWINGS

The various embodiments of the invention can be better understood with reference to the following drawings. The components in the drawings are not necessarily to scale, emphasis instead being placed upon clearly illustrating the principles of the various embodiments of the present invention. In the drawings, like reference numerals designate corresponding parts throughout the several views.

FIG. 1 schematically illustrates the formation of a photonic crystal lattice produced by the interference of four non-coplanar wave vectors according to some embodiments of the present invention.

FIG. 2 schematically illustrates a photo-mask according to some embodiments of the present invention.

FIG. 3 schematically illustrates a photo-mask according to other embodiments of the present invention.

FIG. 4 is a process flow diagram illustrating an exemplary implementation of a method for making photonic crystal devices using a photo-mask.

### DETAILED DESCRIPTION

Referring now to the figures, wherein like reference numerals represent like parts throughout the several views, exemplary embodiments of the present invention will be described in detail. Throughout this description, various components may be identified having specific values or parameters, however, these items are provided as exemplary embodiments. Indeed, the exemplary embodiments do not limit the various aspects and concepts of the present invention as many comparable parameters, sizes, ranges, and/or values may be implemented. The terms “first,” “second,” and the like, “primary,” “secondary,” and the like, do not denote any order, quantity, or importance, but rather are used to distinguish one element from another. Further, the terms “a”, “an”, and “the” do not denote a limitation of quantity, but rather denote the presence of “at least one” of the referenced item.

The various embodiments of the present invention provide improved photo-masks for use in fabricating photonic crystal devices. Methods of making photonic crystal devices, as well as the photonic crystal devices fabricated therefrom, are also provided. The photo-mask generally includes a substrate and a diffractive element layer disposed thereon. The diffractive element layer contains one or more sets of volume gratings, such that each of the one or more sets of volume gratings allows for a single beam of light to pass through to produce four non-coplanar beams of light. Each set of four non-coplanar beams of light can be used to interferometrically produce a specific photonic crystal structure at a specific location within a photosensitive recording material.

Generally, all fourteen 3-dimensional Bravais lattices can be produced by interferometric exposure of four coherent non-coplanar beams. By way of example, for a general triclinic photonic crystal lattice with lattice vector lengths a, b, c with opposite-side angles of α, β, δ, the wave vectors of the four non-coplanar waves are as follows:

$$\begin{matrix}{k}_{1} = k ( {l}_{1} , {m}_{1} , {n}_{1} ) & ( 1 ) \\ {k}_{2} = k ( {l}_{1} - \frac{λ}{a} , {m}_{1} + \frac{λcosγ}{a sin γ} , {n}_{1} + \frac{λ ( cos β - cos αcos γ )}{a {δsin}^{2} γ} ) & ( 2 ) \\ {k}_{3} = k ( {l}_{1} , {m}_{1} - \frac{λ}{b sin γ} , {n}_{1} + \frac{λ ( cos α - cos βcos γ )}{b {δsin}^{2} γ} ) & ( 3 ) \\ {k}_{4} = k ( {l}_{1} , {m}_{1} , {n}_{1} - \frac{λ}{c δ} ) & ( 4 )\end{matrix}$$

where the direction cosines, l₁, m₁, and n₁ are given by

$$\begin{matrix}{l}_{1} = \frac{λ ( bc {sin}^{2} α + a c cos {γsin}^{2} β + ab cos {βsin}^{2} γ )}{2 abc {δ}^{2} {sin}^{2} γ} & ( 5 ) \\ {m}_{1} = \frac{λ [ b ( cos α - cos β cos γ ) + c {sin}^{2} β ]}{2 bc {δ}^{2} sin γ} & ( 6 ) \\ {n}_{1} = \frac{λ}{2 c δ} & ( 7 )\end{matrix}$$

and the wavelength λ must be chosen such that

λ=2abcδ²[a²b²+b²c² sin⁴ α csc⁴ γ+a²c² sin⁴ β csc⁴ γ+2abcsc² γ(a cos α sin² β+b cos β sin² α+c cos γ sin² α sin² βcsc² γ)]^{1/2} (8)

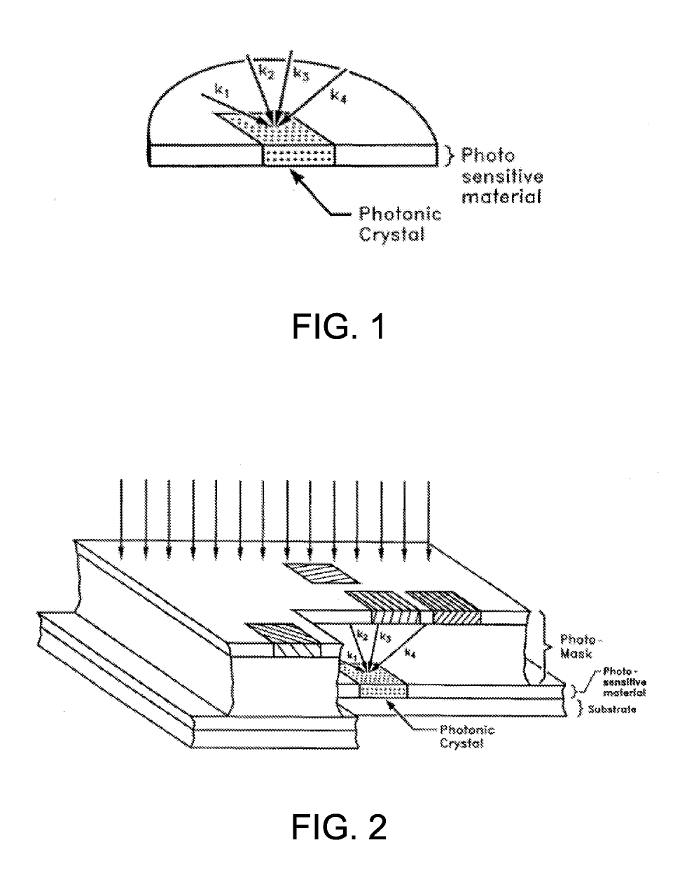

This general set of expressions reduces to relationships for the fourteen Bravais lattices in the appropriate limits. Thus, the triclinic structure can transform to monoclinic, orthorhombic, tetragonal, rhombohedral (trigonal), hexagonal, body-centered orthorhombic, body-centered tetragonal, body-centered monoclinic, body-centered cubic, face-centered orthorhombic, face-centered cubic, base-centered monoclinic, or base-centered orthorhombic lattices. Accordingly, all fourteen Bravais lattices can be realized with the wave vectors given by Equations (1) through (8). These specified four non-coplanar wave vectors, which, upon interference, can be used to produce any Bravais lattice, are depicted schematically in FIG. 1 as k₁, k₂, k₃, and k₄. Because any of the 14 Bravais lattices can be produced, any crystallographic (and more specifically, any photonic crystal) structure can also be produced in, for example, a photosensitive material.

The present inventive photo-mask devices provide new methods for producing these beams in a practical manufacturing-oriented manner such that many photonic crystal devices could be fabricated in parallel over an entire wafer. The photo-masks are produced by creating a plurality of diffractive elements and/or refractive elements in a body element or substrate. For example, the methods disclosed in commonly-assigned U.S. Pat. Nos. 6,285,813 and 6,606,432 can be used to produce diffractive elements, such as volume gratings, in the photo-mask. For example, one method in U.S. Pat. No. 6,285,813 teaches splitting a coherent light beam into a first coherent light beam and a second light beam. The first coherent light beam is directed into a first lens and onto an optical component, such as a prism. The second coherent light beam is directed into a second lens and onto the optical component. The optical component optically transmits the first and second coherent light beams into a recording material to create a diffractive grating. Further, U.S. Pat. No. 6,606,432 provides a method for producing multiple diffraction gratings in a single recording material, which can serve as a phase mask.

In contrast, to produce refractive elements in the photo-mask, additional components having different indices of refraction from the primary component of the photo-mask (e.g., air, polymers, glass, and the like) can be incorporated into various regions of the photo-mask. These refractive elements can be used to alter the direction of the light exiting the photo-mask.

It is important to note that a combination of diffractive elements and refractive elements can be used. That is, the various embodiments of the photo-masks are not limited to having only diffractive elements or only refractive elements.

Generally speaking, the photo-masks can manipulate light to produce interference patterns on the recording material, such that the crystal structure of the photonic crystal device of is determined by the interference patterns themselves. A portion of such a photo-mask is shown in FIG. 2. The photo-mask can include many sets of diffractive elements and/or refractive elements, each set producing four non-coplanar beams, and each set fabricating a specific photonic crystal structure at a specified location in the photosensitive recording material. Thus, the inventive photo-masks can be directly used for wafer-scale fabrication of multitudes of photonic crystal devices in a single exposure. For example, the photo-masks can be used in a mask aligner.

Each set of diffractive elements used to generate the four non-coplanar beams can include two or more diffractive elements. In an exemplary embodiment, each set of diffractive elements comprises four diffractive elements. In this manner, each diffractive element of the set produces one non-coplanar beam of light. Once again, the sets diffractive elements can be produced using the methods described in U.S. Pat. No. 6,285,813 and in U.S. Pat. No. 6,606,432, the contents of both of which are incorporated by reference in their entireties as if fully set forth herein.

In addition, the photo-mask optionally can incorporate a chrome pattern layer on the side adjacent to the recording material. The chrome layers can then delineate regions where the photonic crystal structure will be fabricated on the recording material. Specifically, only the angularly deviated light that passes through the transparent portions of the chrome layer can be exposed to the recording material.

The polarization of the beams can be chosen to produce controlled pattern contrast. Such methods for selecting the polarization to control the contrast are known to those skilled in the art to which this disclosure pertains. The inventive photo-mask extends this previous work in that the present photo-mask can include a retarder layer (equivalent to a half-wave plate) to rotate the input linear polarization at each diffractive element site. This would be done to optimize the polarization for recording when this is needed.

If the intensity of a beam is too large, the excess power can be attenuated by introducing an absorption layer at the site of each diffractive element.

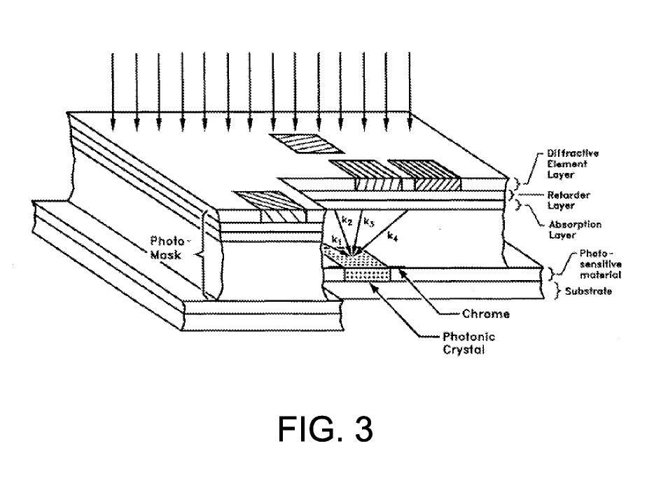

Such a photo-mask is shown in FIG. 3. This photo-mask includes a retarder layer and an absorption layer at selected diffractive element sites, and also shows a chrome layer at selected sites of the photosensitive recording material.

In exemplary embodiments, the substrates or body elements can be formed from a glass such as fused silica, borosilicate crown glass (e.g., BK-7), or other similar glasses. Alternatively, the substrates or body elements can be formed from any material suitable for use in a photo-mask such as a photosensitive material (e.g., photorefractive crystals, organic volume phase holographic materials, or the like). In exemplary embodiments, the recording materials are photosensitive compositions such as those listed immediately above.

Advantageously, the photo-masks disclosed herein provide a means for interferometrically producing photonic crystal devices with a single collimated exposure beam rather than using four non-coplanar beams that need to be individually accurately aligned. The inventive photo-masks produce all four needed beams by way of diffractive elements and/or refractive elements that are incorporated in the photo-mask. The resulting mask is simple to use with existing photolithography masking technology. Further, once the mask is fabricated, it can be subsequently repetitively used many times.

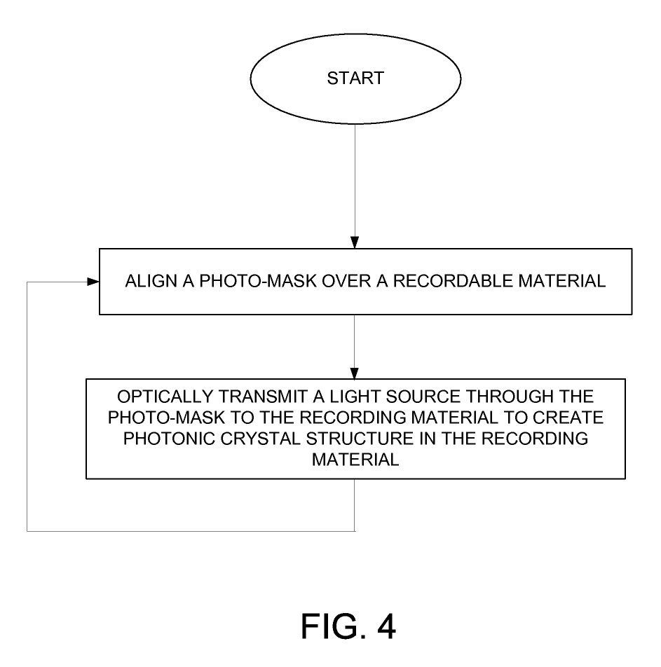

FIG. 4 is a flow diagram illustrating an exemplary implementation of a method for making one or more photonic crystal structures using a photo-mask. To create the photonic crystal devices, the photo-mask is aligned over the recording material on which the photonic crystal structure is to be created. Once the photo-mask is aligned over the recording material, light produced by a light source is directed or optically transmitted through the photo mask to the recording material to create the photonic crystal structure in the recording material. Using this method, a plurality of photonic crystal structures may be created substantially simultaneously as the light is coupled to the recording material.

The embodiments of the present invention are not limited to the particular formulations, process steps, and materials disclosed herein as such formulations, process steps, and materials may vary somewhat. Moreover, the terminology employed herein is used for the purpose of describing exemplary embodiments only and the terminology is not intended to be limiting since the scope of the various embodiments of the present invention will be limited only by the appended claims and equivalents thereof. For example, temperature and pressure parameters may vary depending on the particular materials used.

Therefore, while embodiments of this disclosure have been described in detail with particular reference to exemplary embodiments, those skilled in the art will understand that variations and modifications can be effected within the scope of the disclosure as defined in the appended claims. Accordingly, the scope of the various embodiments of the present invention should not be limited to the above discussed embodiments, and should only be defined by the following claims and all equivalents.

What is claimed is:

1. A photo-mask for producing a photonic crystal device, comprising:
a body element; and
a set of diffractive elements and/or refractive elements disposed on the body element or within the body element;
wherein the set of diffractive elements and/or refractive elements is configured to produce four non-coplanar beams of light when a beam of light is passed therethrough.

2. The photo-mask of claim 1, wherein the photo-mask further comprises a chrome layer.

3. The photo-mask of claim 1, wherein the photo-mask further comprises an absorption layer.

4. The photo-mask of claim 1, wherein the photo-mask further comprises a retarder layer.

5. The photo-mask of claim 1, wherein the diffractive elements comprise one or more volume gratings or surface-relief gratings.

6. The photo-mask of claim 1, wherein the refractive elements comprise one or more materials having a different index of refraction than the body element.

7. The photo-mask of claim 1, wherein the set of diffractive elements and/or refractive elements comprises two or more diffractive elements and/or refractive elements.

8. The photo-mask of claim 1, wherein the set of diffractive elements and/or refractive elements comprises four diffractive elements and/or refractive elements.

9. The photo-mask of claim 1, further comprising one or more additional sets of diffractive elements and/or refractive elements disposed on the body element or within the body element, wherein each additional set of diffractive elements and/or refractive elements is configured to produce four non-coplanar beams of light when a beam of light is passed therethrough.

10. An apparatus for producing a photonic crystal device, comprising:
a photo-mask comprising a set of diffractive elements and/or refractive elements disposed on a body element or within the body element; and
a recording material;
wherein the set of diffractive elements and/or refractive elements is configured to produce four non-coplanar beams of light when a beam of light is passed therethrough such that the four non-coplanar beams of light interferometrically produce a photonic crystal structure at a specific location in the recording material.

11. The apparatus of claim 10, wherein the photo-mask further comprises one or more of a chrome layer, absorption layer, or retarder layer.

12. The apparatus of claim 10, wherein the diffractive elements comprise volume gratings or surface-relief gratings.

13. The apparatus of claim 10, wherein the refractive elements comprise materials having a different index of refraction than the body element.

14. The apparatus of claim 10, wherein the set of diffractive elements and/or refractive elements comprises two or more diffractive elements and/or refractive elements.

15. The apparatus of claim 10, wherein the set of diffractive elements and/or refractive elements comprises four diffractive elements and/or refractive elements.

16. The apparatus of claim 10, wherein the photo-mask further comprises one or more additional sets of diffractive elements and/or refractive elements disposed on the body element or within the body element, wherein each additional set of diffractive elements and/or refractive elements is configured to produce four non-coplanar beams of light when a beam of light is passed therethrough.

17. A method of fabricating a photonic crystal device, the method comprising:
generating a light beam;
directing the light beam into a photo-mask having a set of diffractive elements and/or refractive elements to produce four non-coplanar beams of light; and
focusing the four non-coplanar beams of light in a photosensitive recording material to interferometrically produce a photonic crystal structure in the photosensitive recording material.

18. The method of claim 17, further comprising:
aligning the photo-mask over a second portion of the recording material; and
repeating the generating, directing, and focusing on the second portion of the recording material.

19. The method of claim 17, wherein the photo-mask further comprises one or more of a chrome layer, absorption layer, or retarder layer.

20. The method of claim 17, wherein the photo-mask further comprises one or more additional sets of diffractive elements and/or refractive elements, wherein directing the light beam into the photo-mask produces four non-coplanar beams of light for each additional set of diffractive elements and/or refractive elements, and each set of four non-coplanar beams is focused in the photosensitive recording material to interferometrically produce additional photonic crystal structures in the photosensitive recording material.
